(19) United States
(12) Patent Application Publication
(10) Pub. No.: US 2026/0039262 A1
(43) Pub. Date: Feb. 5, 2026

(54) MULTIPLE LEVEL ENVELOPE TRACKING USING HALF BRIDGES

(71) Applicant: Samsung Electronics Co., Ltd., Suwon-si (KR)

(72) Inventors: Xinguang Xu, Allen, TX (US); Navneet Sharma, Allen, TX (US); Won Suk Choi, McKinney, TX (US); Shenggang Dong, Dallas, TX (US); Feng Qi, Richardson, TX (US); Gang Xu, Allen, TX (US)

(21) Appl. No.: 19/189,167

(22) Filed: Apr. 24, 2025

Related U.S. Application Data
(60) Provisional application No. 63/679,472, filed on Aug. 5, 2024.

(51) Int. Cl. H03F 3/213

(52) U.S. Cl. CPC H03F 3/213; H03F 2200/102

(57) ABSTRACT

Methods and systems multiple level envelope tracking using multi half bridges. A power modulator system includes one or more power supply modulators configured to provide a power amplifier drain voltage, each of the one or more power supply modulators including, one or more half bridges including one or more drivers, and one or more logic and dead time adjust circuits. A method includes generating one or more power supply modulators using one or more half bridges, providing power amplifier drain voltage based on the one or more power supply modulators, and setting a dead time set for each of the one or more half bridges using one or more logic and dead time adjust circuits.

### CROSS-REFERENCE TO RELATED APPLICATIONS AND CLAIM OF PRIORITY

The present application claims priority to U.S. Provisional Patent Application No. 63/679,472, filed on Aug. 5, 2024. The contents of the above-identified patent documents are incorporated herein by reference.

### TECHNICAL FIELD

The present disclosure relates generally to wireless communication systems. More specifically, the present disclosure relates to a system and method for multiple level envelope tracking using half bridges.

### BACKGROUND

In 6G extreme-MIMO systems, there are likely to be over a thousand power amplifiers in a single base station. These power amplifiers typically consume the majority of the power budget of the base station. Moreover, their power-added efficiency (PAE), the main performance metric of a power amplifier, is often as low as 20%. The lower PAE is indicative of wasted power that contributes significantly to thermal concerns and increases the operational expenditure costs of a system. To address this, digital envelope tracking is used to improve power efficiency at different power backoff levels. However, the amount of power supplies required by the digital envelope tracking system complicate implementation in large MIMO systems.

Accordingly, there is a need for systems and methods for improved envelope tracking systems that overcome these challenges.

### SUMMARY

The present disclosure relates generally to wireless communication systems and, more specifically, the present disclosure relates to a system and method for multiple level envelope tracking using half bridges.

In one embodiment, a power modulator system is provided. The power modulator system includes one or more power supply modulators configured to provide a power amplifier drain voltage, each of the one or more power supply modulators including, one or more half bridges including one or more drivers, and one or more logic and dead time adjust circuits.

In another embodiment, a method is provided. The method includes generating one or more power supply modulators using one or more half bridges, providing power amplifier drain voltage based on the one or more power supply modulators, and setting a dead time set for each of the one or more half bridges.

In yet another embodiment, an electronic device is provided. The electronic device includes one or more trackers, one or more power amplifiers, and a processor operably coupled to the one or more trackers and the one or more power amplifiers. The processor is configured to cause the electronic device to generate one or more power supply modulators using one or more half bridges, provide power amplifier drain voltage based on the one or more power supply modulators, and set a dead time set for each of the one or more half bridges.

Other technical features may be readily apparent to one skilled in the art from the following figures, descriptions, and claims.

Before undertaking the DETAILED DESCRIPTION below, it may be advantageous to set forth definitions of certain words and phrases used throughout this patent document. The term “couple” and its derivatives refer to any direct or indirect communication between two or more elements, whether or not those elements are in physical contact with one another. The terms “transmit,” “receive,” and “communicate,” as well as derivatives thereof, encompass both direct and indirect communication. The terms “include” and “comprise,” as well as derivatives thereof, mean inclusion without limitation. The term “or” is inclusive, meaning and/or. The phrase “associated with,” as well as derivatives thereof, means to include, be included within, interconnect with, contain, be contained within, connect to or with, couple to or with, be communicable with, cooperate with, interleave, juxtapose, be proximate to, be bound to or with, have, have a property of, have a relationship to or with, or the like. The term “controller” means any device, system, or part thereof that controls at least one operation. Such a controller may be implemented in hardware or a combination of hardware and software and/or firmware. The functionality associated with any particular controller may be centralized or distributed, whether locally or remotely. The phrase “at least one of,” when used with a list of items, means that different combinations of one or more of the listed items may be used, and only one item in the list may be needed. For example, “at least one of: A, B, and C” includes any of the following combinations: A, B, C, A and B, A and C, B and C, and A and B and C.

Moreover, various functions described below can be implemented or supported by one or more computer programs, each of which is formed from computer readable program code and embodied in a computer readable medium. The terms “application” and “program” refer to one or more computer programs, software components, sets of instructions, procedures, functions, objects, classes, instances, related data, or a portion thereof adapted for implementation in a suitable computer readable program code. The phrase “computer readable program code” includes any type of computer code, including source code, object code, and executable code. The phrase “computer readable medium” includes any type of medium capable of being accessed by a computer, such as read only memory (ROM), random access memory (RAM), a hard disk drive, a compact disc (CD), a digital video disc (DVD), or any other type of memory. A “non-transitory” computer readable medium excludes wired, wireless, optical, or other communication links that transport transitory electrical or other signals. A non-transitory computer readable medium includes media where data can be permanently stored and media where data can be stored and later overwritten, such as a rewritable optical disc or an erasable memory device.

Definitions for other certain words and phrases are provided throughout this patent document. Those of ordinary skill in the art should understand that in many if not most instances, such definitions apply to prior as well as future uses of such defined words and phrases.

### BRIEF DESCRIPTION OF THE DRAWINGS

For a more complete understanding of the present disclosure and its advantages, reference is now made to the following description taken in conjunction with the accompanying drawings, in which like reference numerals represent like parts:

FIG. 1 illustrates an example wireless network according to embodiments of the present disclosure;

FIG. 2 illustrates an example gNB according to embodiments of the present disclosure;

FIG. 3 illustrates an example UE according to embodiments of the present disclosure;

FIG. 4 a digital envelope tracking system according to embodiments of the present disclosure;

FIG. 5 illustrates an example block diagram of a half bridge to support multiple level envelope tracking according to embodiments of the present disclosure;

FIG. 6 illustrates an example block diagram of a switch capacitor voltage divider to support multiple level envelope tracking according to embodiments of the present disclosure;

FIG. 7 illustrates an example block diagram of a supply voltage modulator to support multiple level envelope tracking according to embodiments of the present disclosure;

FIG. 8 illustrates an example block diagram of a voltage supply system to support multiple level envelope tracking according to embodiments of the present disclosure;

FIG. 9 illustrates an example block diagram of a voltage supply system using multi-level supply voltage modulators to support multiple level envelope tracking according to embodiments of the present disclosure; and

FIG. 10 illustrates an example flow chart of a method for applying multiple level envelope tracking using multi half bridges according to embodiments of the present disclosure.

### DETAILED DESCRIPTION

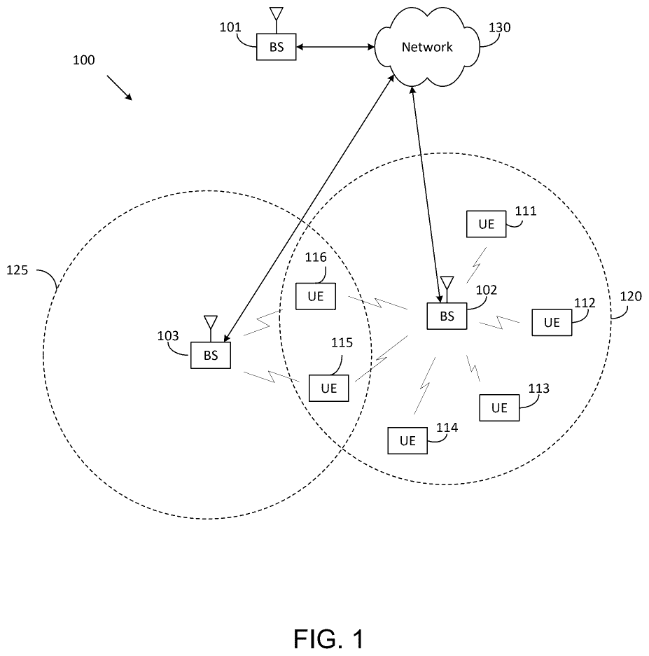

FIG. 1 through FIG. 10, discussed below, and the various embodiments used to describe the principles of the present disclosure in this patent document are by way of illustration only and should not be construed in any way to limit the scope of the disclosure. Those skilled in the art will understand that the principles of the present disclosure may be implemented in any suitably arranged system or device.

As introduced above, power amplifiers typically consume the majority of the power budget of the base station. Moreover, their power-added efficiency (PAE), the main performance metric of a power amplifier, is often as low as 20%. The lower PAE is indicative of wasted power that contributes significantly to thermal concerns and increases the operational expenditure costs of a system. Additionally, the PAE tends to be lower for higher RF frequencies, further exacerbating the challenge for 6G design where Frequency Range 3 upper mid-band is being considered.

Digital envelope tracking (DET) improves the PAE of a power amplifier by reducing the bias voltage whenever possible. In a DET system, the power tracking and envelope tracking modulator is a DC power modulator that modulates the power amplifier drain supply by following the power and envelope of a baseband signal. In particular, the modulator is usually a DC switch supply or power digital-to-analog converter (DAC) to achieve multi-level DC supply. The 8-level power DAC, however, may need four individual DC power supply, and an 8-level DC switch supply may need eight individual DC supplies. This creates conflict and increases implementation cost related to DC supply. Additionally, the amount of DC supplies needed increase the difficulty of setting a dead time needed to protect the switch circuits from damage (e.g., from being burned).

The present disclosure provides systems and methods for multiple level envelope tracking using multi half bridges. As described herein, the present disclosure includes a system that uses one or more half bridges to generate one or more power supply modulators with multiple levels. The power supply modulator is generated to have an even-numbered integer (e.g., 2, 4, 6, 8, 10, 12, etc.) level and an output power in an inclusive range between 0.5 W and 1000 W. Additionally, the present disclosure allows for a dead time to be set for each half bridge to avoid burning a field-effect transistor (FET).

To meet the demand for wireless data traffic having increased since deployment of 4G communication systems and to enable various vertical applications, 5G/NR communication systems have been developed and are currently being deployed. The 5G/NR communication system is considered to be implemented in higher frequency (mmWave) bands, e.g., 28 GHz or 60 GHz bands, so as to accomplish higher data rates or in lower frequency bands, such as 6 GHZ, to enable robust coverage and mobility support. To decrease propagation loss of the radio waves and increase the transmission distance, the beamforming, massive multiple-input multiple-output (MIMO), full dimensional MIMO (FD-MIMO), array antenna, an analog beam forming, large scale antenna techniques are discussed in 5G/NR communication systems.

In addition, in 5G/NR communication systems, development for system network improvement is under way based on advanced small cells, cloud radio access networks (RANs), ultra-dense networks, device-to-device (D2D) communication, wireless backhaul, moving network, cooperative communication, coordinated multi-points (COMP), reception-end interference cancelation and the like.

The discussion of 5G systems and frequency bands associated therewith is for reference as certain embodiments of the present disclosure may be implemented in 5G systems. However, the present disclosure is not limited to 5G systems or the frequency bands associated therewith, and embodiments of the present disclosure may be utilized in connection with any frequency band. For example, aspects of the present disclosure may also be applied to deployment of 5G communication systems, 6G or even later releases which may use terahertz (THz) bands.

FIGS. 1-3 below describe various embodiments implemented in wireless communications systems and with the use of orthogonal frequency division multiplexing (OFDM) or orthogonal frequency division multiple access (OFDMA) communication techniques. The descriptions of FIGS. 1-3 are not meant to imply physical or architectural limitations to the manner in which different embodiments may be implemented. Different embodiments of the present disclosure may be implemented in any suitably arranged communications system.

FIG. 1 illustrates an example wireless network according to embodiments of the present disclosure. The embodiment of the wireless network shown in FIG. 1 is for illustration only. Other embodiments of the wireless network 100 could be used without departing from the scope of this disclosure.

As shown in FIG. 1, the wireless network includes a gNB 101 (e.g., base station, BS), a gNB 102, and a gNB 103. The gNB 101 communicates with the gNB 102 and the gNB 103. The gNB 101 also communicates with at least one network 130, such as the Internet, a proprietary Internet Protocol (IP) network, or other data network.

The gNB 102 provides wireless broadband access to the network 130 for a first plurality of user equipments (UEs) within a coverage area 120 of the gNB 102. The first plurality of UEs includes a UE 111, which may be located in a small business; a UE 112, which may be located in an enterprise; a UE 113, which may be a Wifi hotspot; a UE 114, which may be located in a first residence; a UE 115, which may be located in a second residence; and a UE 116, which may be a mobile device, such as a cell phone, a wireless laptop, a wireless PDA, or the like. The gNB 103 provides wireless broadband access to the network 130 for a second plurality of UEs within a coverage area 125 of the gNB 103. The second plurality of UEs includes the UE 115 and the UE 116. In some embodiments, one or more of the gNBs 101-103 may communicate with each other and with the UEs 111-116 using 5G/NR, long term evolution (LTE), long term evolution-advanced (LTE-A), WiMAX, WiFi, or other wireless communication techniques.

Depending on the network type, the term “base station” or “BS” can refer to any component (or collection of components) configured to provide wireless access to a network, such as transmit point (TP), transmit-receive point (TRP), an enhanced base station (eNodeB or eNB), a 5G/NR base station (gNB), a macrocell, a femtocell, a WiFi access point (AP), or other wirelessly enabled devices. Base stations may provide wireless access in accordance with one or more wireless communication protocols, e.g., 5G/NR 3rd generation partnership project (3GPP) NR, long term evolution (LTE), LTE advanced (LTE-A), high speed packet access (HSPA), Wi-Fi 802.11a/b/g/n/ac, etc. For the sake of convenience, the terms “BS” and “TRP” are used interchangeably in this patent document to refer to network infrastructure components that provide wireless access to remote terminals. Also, depending on the network type, the term “user equipment” or “UE” can refer to any component such as “mobile station,” “subscriber station,” “remote terminal,” “wireless terminal,” “receive point,” or “user device.” For the sake of convenience, the terms “user equipment” and “UE” are used in this patent document to refer to remote wireless equipment that wirelessly accesses a BS, whether the UE is a mobile device (such as a mobile telephone or smartphone) or is normally considered a stationary device (such as a desktop computer or vending machine).

Dotted lines show the approximate extents of the coverage areas 120 and 125, which are shown as approximately circular for the purposes of illustration and explanation only. It should be clearly understood that the coverage areas associated with gNBs, such as the coverage areas 120 and 125, may have other shapes, including irregular shapes, depending upon the configuration of the gNBs and variations in the radio environment associated with natural and man-made obstructions.

Although FIG. 1 illustrates one example of a wireless network, various changes may be made to FIG. 1. For example, the wireless network could include any number of gNBs and any number of UEs in any suitable arrangement. Also, the gNB 101 could communicate directly with any number of UEs and provide those UEs with wireless broadband access to the network 130. Similarly, each gNB 102-103 could communicate directly with the network 130 and provide UEs with direct wireless broadband access to the network 130. Further, the gNBs 101, 102, and/or 103 could provide access to other or additional external networks, such as external telephone networks or other types of data networks.

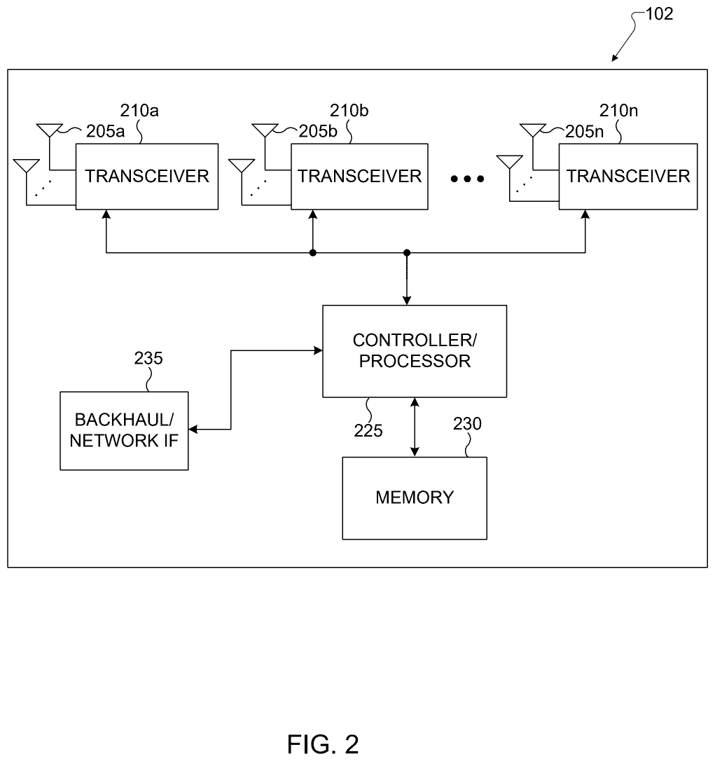

FIG. 2 illustrates an example gNB 102 according to embodiments of the present disclosure. The embodiment of the gNB 102 illustrated in FIG. 2 is for illustration only, and the gNBs 101 and 103 of FIG. 1 could have the same or similar configuration. However, gNBs come in a wide variety of configurations, and FIG. 2 does not limit the scope of this disclosure to any particular implementation of a gNB.

As shown in FIG. 2, the gNB 102 includes multiple antennas 205a-205n, multiple transceivers 210a-210n, a controller/processor 225, a memory 230, and a backhaul or network interface 235.

The transceivers 210a-210n receive, from the antennas 205a-205n, incoming RF signals, such as signals transmitted by UEs in the network 100. The transceivers 210a-210n down-convert the incoming RF signals to generate IF or baseband signals. The IF or baseband signals are processed by receive (RX) processing circuitry in the transceivers 210a-210n and/or controller/processor 225, which generates processed baseband signals by filtering, decoding, and/or digitizing the baseband or IF signals. The controller/processor 225 may further process the baseband signals.

Transmit (TX) processing circuitry in the transceivers 210a-210n and/or controller/processor 225 receives analog or digital data (such as voice data, web data, e-mail, or interactive video game data) from the controller/processor 225. The TX processing circuitry encodes, multiplexes, and/or digitizes the outgoing baseband data to generate processed baseband or IF signals. The transceivers 210a-210n up-converts the baseband or IF signals to RF signals that are transmitted via the antennas 205a-205n.

The controller/processor 225 can include one or more processors or other processing devices that control the overall operation of the gNB 102. For example, the controller/processor 225 could control the reception of UL channel signals and the transmission of DL channel signals by the transceivers 210a-210n in accordance with well-known principles. The controller/processor 225 could support additional functions as well, such as more advanced wireless communication functions. For instance, the controller/processor 225 could support beam forming or directional routing operations in which outgoing/incoming signals from/to multiple antennas 205a-205n are weighted differently to effectively steer the outgoing signals in a desired direction. Any of a wide variety of other functions could be supported in the gNB 102 by the controller/processor 225.

The controller/processor 225 is also capable of executing programs and other processes resident in the memory 230, such as an OS. The controller/processor 225 can move data into or out of the memory 230 as required by an executing process.

The controller/processor 225 is also coupled to the backhaul or network interface 235. The backhaul or network interface 235 allows the gNB 102 to communicate with other devices or systems over a backhaul connection or over a network. The interface 235 could support communications over any suitable wired or wireless connection(s). For example, when the gNB 102 is implemented as part of a cellular communication system (such as one supporting 5G/NR, LTE, or LTE-A), the interface 235 could allow the gNB 102 to communicate with other gNBs over a wired or wireless backhaul connection. When the gNB 102 is implemented as an access point, the interface 235 could allow the gNB 102 to communicate over a wired or wireless local area network or over a wired or wireless connection to a larger network (such as the Internet). The interface 235 includes any suitable structure supporting communications over a wired or wireless connection, such as an Ethernet or transceiver.

The memory 230 is coupled to the controller/processor 225. Part of the memory 230 could include a RAM, and another part of the memory 230 could include a Flash memory or other ROM.

Although FIG. 2 illustrates one example of gNB 102, various changes may be made to FIG. 2. For example, the gNB 102 could include any number of each component shown in FIG. 2. Also, various components in FIG. 2 could be combined, further subdivided, or omitted and additional components could be added according to particular needs.

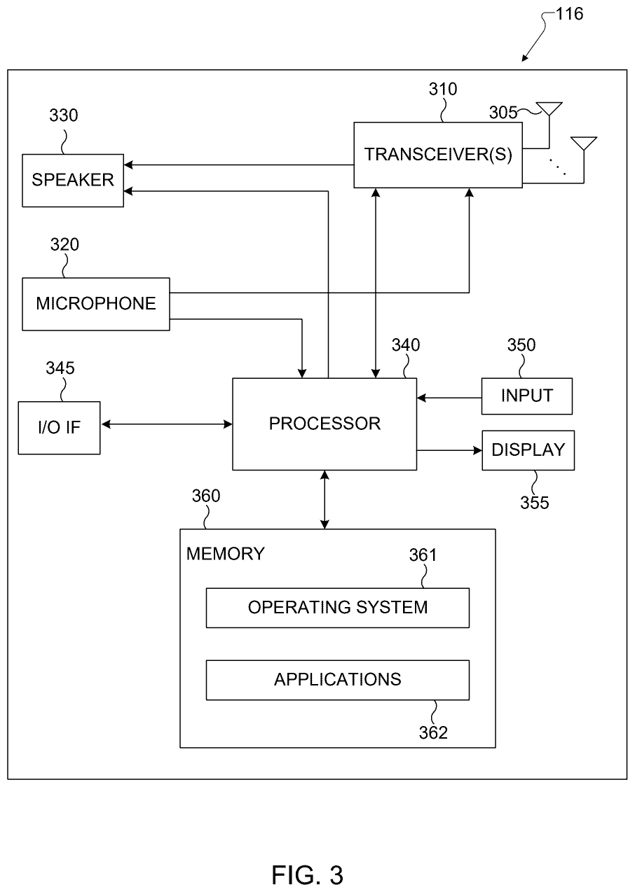

FIG. 3 illustrates an example UE 116 according to embodiments of the present disclosure. The embodiment of the UE 116 illustrated in FIG. 3 is for illustration only, and the UEs 111-115 of FIG. 1 could have the same or similar configuration. However, UEs come in a wide variety of configurations, and FIG. 3 does not limit the scope of this disclosure to any particular implementation of a UE.

As shown in FIG. 3, the UE 116 includes antenna(s) 305, a transceiver(s) 310, and a microphone 320. The UE 116 also includes a speaker 330, a processor 340, an input/output (I/O) interface (IF) 345, an input 350, a display 355, and a memory 360. The memory 360 includes an operating system (OS) 361 and one or more applications 362.

The transceiver(s) 310 receives, from the antenna 305, an incoming RF signal transmitted by a gNB of the network 100. The transceiver(s) 310 down-converts the incoming RF signal to generate an intermediate frequency (IF) or baseband signal. The IF or baseband signal is processed by RX processing circuitry in the transceiver(s) 310 and/or processor 340, which generates a processed baseband signal by filtering, decoding, and/or digitizing the baseband or IF signal. The RX processing circuitry sends the processed baseband signal to the speaker 330 (such as for voice data) or is processed by the processor 340 (such as for web browsing data).

TX processing circuitry in the transceiver(s) 310 and/or processor 340 receives analog or digital voice data from the microphone 320 or other outgoing baseband data (such as web data, e-mail, or interactive video game data) from the processor 340. The TX processing circuitry encodes, multiplexes, and/or digitizes the outgoing baseband data to generate a processed baseband or IF signal. The transceiver(s) 310 up-converts the baseband or IF signal to an RF signal that is transmitted via the antenna(s) 305.

The processor 340 can include one or more processors or other processing devices and execute the OS 361 stored in the memory 360 in order to control the overall operation of the UE 116. For example, the processor 340 could control the reception of DL channel signals and the transmission of UL channel signals by the transceiver(s) 310 in accordance with well-known principles. In some embodiments, the processor 340 includes at least one microprocessor or microcontroller.

The processor 340 is also capable of executing other processes and programs resident in the memory 360. The processor 340 can move data into or out of the memory 360 as required by an executing process. In some embodiments, the processor 340 is configured to execute the applications 362 based on the OS 361 or in response to signals received from gNBs or an operator. The processor 340 is also coupled to the I/O interface 345, which provides the UE 116 with the ability to connect to other devices, such as laptop computers and handheld computers. The I/O interface 345 is the communication path between these accessories and the processor 340.

The processor 340 is also coupled to the input 350, which includes for example, a touchscreen, keypad, etc., and the display 355. The operator of the UE 116 can use the input 350 to enter data into the UE 116. The display 355 may be a liquid crystal display, light emitting diode display, or other display capable of rendering text and/or at least limited graphics, such as from web sites.

The memory 360 is coupled to the processor 340. Part of the memory 360 could include a random-access memory (RAM), and another part of the memory 360 could include a Flash memory or other read-only memory (ROM).

Although FIG. 3 illustrates one example of UE 116, various changes may be made to FIG. 3. For example, various components in FIG. 3 could be combined, further subdivided, or omitted and additional components could be added according to particular needs. As a particular example, the processor 340 could be divided into multiple processors, such as one or more central processing units (CPUs) and one or more graphics processing units (GPUs). In another example, the transceiver(s) 310 may include any number of transceivers and signal processing chains and may be connected to any number of antennas. Also, while FIG. 3 illustrates the UE 116 configured as a mobile telephone or smartphone, UEs could be configured to operate as other types of mobile or stationary devices.

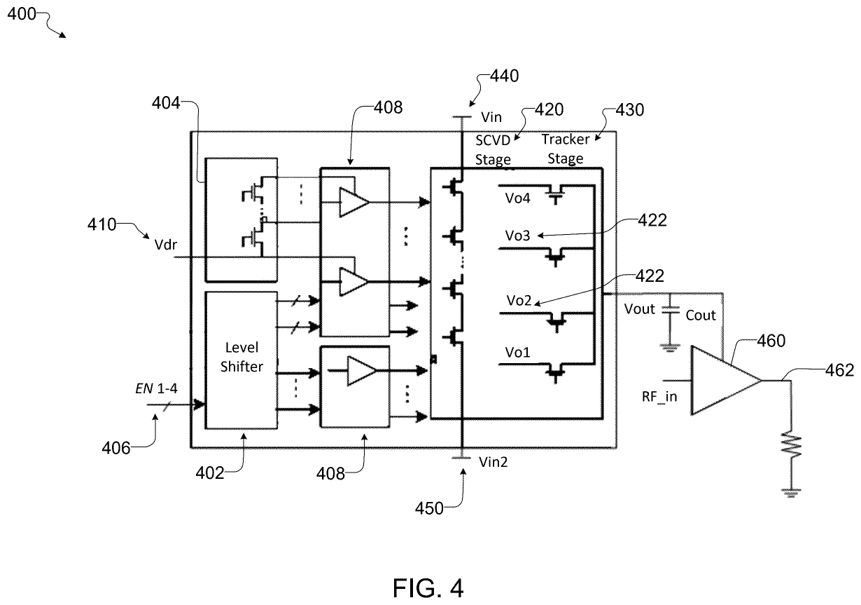

The TX processing circuitry of the gNB 101 may also include one or more power amplifiers coupled to one or more digital-to-analog converters and configured to amplify the baseband signal prior to transmission using the antenna. The one or more power amplifiers receive a supply voltage sufficient to cover the signal envelope of the baseband signal, as shown in FIG. 4.

FIG. 4 illustrates a digital envelope tracking system 400 according to embodiments of the present disclosure. For ease of explanation, the digital envelope tracking system 400 will be described as including one or more components of the wireless network 100 of FIG. 1, such as the gNB 102; however, the digital envelope tracking system 400 could be implemented using any other suitable device or system. The embodiment of the digital envelope tracking system 400 shown in FIG. 4 is for illustration only. Other embodiments of the digital envelope tracking system 400 could be used without departing from the scope of this disclosure.

As shown in FIG. 4, the digital envelope tracking system 400 includes a level shifter 402 and a bootstrap 404. The level shifter 402 is configured to receive an envelope signal 406 (e.g., from a gNB 102) and level shift the envelope signal 406 before passing it to one or more gate drivers 408. The envelope signal 406 and the one or more gate drivers 408 are configured to receive a driver voltage 410. The signals from the one or more gate drivers 408 are provided to a generator 420 and a tracker 430. The generator may be a switch capacitor voltage divider (SVD) or other suitable voltage divider configured to produce one or more voltages. The generator 420 also receives a first voltage 440 and a second voltage 450. The first voltage 440 is a high voltage and the second voltage 450 is a low voltage, meaning that the first voltage 440 includes a first voltage level and the second voltage includes a second voltage level that is less than the first voltage level of the first voltage 440. The generator 420 uses the first voltage 440 and the second voltage 450 to generate one or more intermediate voltages 422. That is, the generator 420 generates one or more intermediate voltages 422 having voltage levels between the first voltage 440 and the second voltage 450. For example, the generator 420 may generate two intermediate voltages 422 where a first intermediate voltage includes a voltage level of one-third of the difference between the first voltage 440 and the second voltage 450 and a second intermediate voltage includes a voltage level of two-thirds of the difference between the first voltage 440 and the second voltage 450. Alternatively, other intermediate voltage levels may be used, such as non-uniform voltages or more than two intermediate voltages, such as three or more.

The tracker 430 receives the first voltage 440, the second voltage 450, and the one or more intermediate voltages 422 and provides them to a power amplifier 460. The power amplifier 460 then uses the first voltage 440, the second voltage 450, and the one or more intermediate voltages 422 to amplify an RF signal corresponding to the envelope signal 406 to produce an output signal 462.

As shown in FIG. 4, the generator 420 includes six switches and the tracker 430 includes four switches. This configuration allows for four voltage levels (e.g., the first voltage 440, the second voltage 450, and two of the one or more intermediate voltages 422) to be provided to the power amplifier 460. For example, two switches are coupled to the first voltage 440 and configured to generate a first of the one or more intermediate voltages 422, an additional two switches are coupled to the first of the one or more intermediate voltages 422 and configured to generate a second of the one or more intermediate voltages 422, and a third set of two switches are coupled between the second of the one or more intermediate voltages 422 and the second voltage 450. Additionally, the each of the four switches of the tracker 430 are configured to receive one of the first voltage 440, the second voltage 450, the first of the one or more intermediate voltages 422, or the second of the one or more intermediate voltages 422. The tracker 430 then determines which of the voltages (e.g., the first voltage 440, the second voltage 450, the first of the one or more intermediate voltages 422, or the second of the one or more intermediate voltages 422) to provide to the power amplifier 460 based on the envelope signal 406.

Although FIG. 4 illustrates one example of a digital envelope tracking system, various changes may be made to FIG. 4. For example, various components in FIG. 4 could be combined, further subdivided, or omitted and additional components could be added according to particular needs.

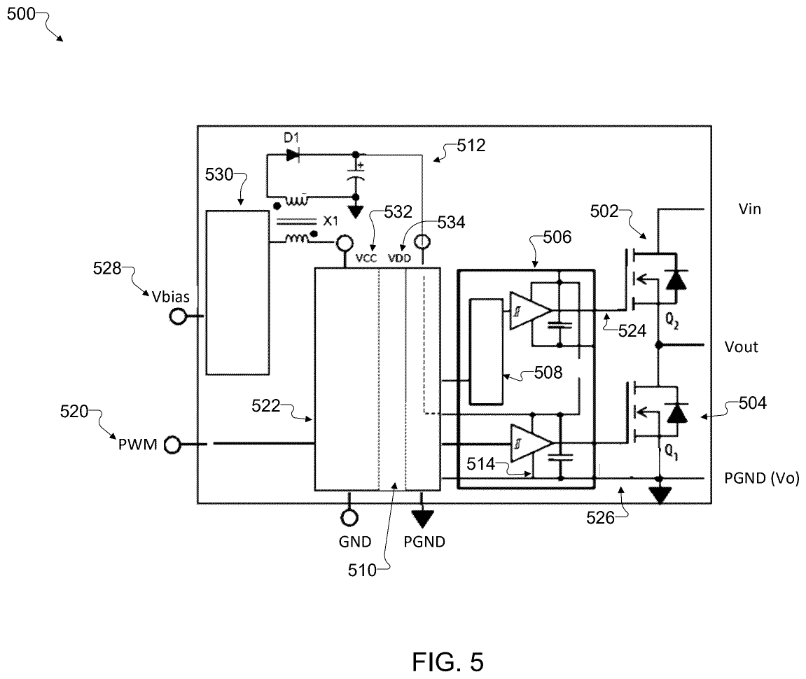

FIG. 5 illustrates an example block diagram of a half bridge 500 to support multiple level envelope tracking according to embodiments of the present disclosure. In particular, the half bridge 500 may be used as one or more of the switches in the generator 420 or the tracker 430 of FIG. 4. The embodiment of the half bridge 500 illustrated in FIG. 5 is for illustration only. Other embodiments of the half bridge 500 could be used without departing from the scope of the present disclosure.

As shown in FIG. 5, the half bridge 500 includes a first transistor 502, a second transistor 504, a driver 506, a level shifter 508, an isolated buffer amplifier 510, a bootstrap 512, and a low dropout regulator 514. The half bridge 500 uses the first transistor 502 and the second transistor 504, connected in series, to alternate between two states, creating a pulsed output voltage. The pulsed output voltage may include a square wave or pulse width modulated (PWM) waveform that is bipolar, meaning that the waveform oscillates between positive and negative values.

The first transistor 502 and the second transistor 504 may be any suitable transistors, such as gallium nitride field-effect transistors (GaNFETs) or metal-oxide-semiconductor field-effect transistors (MOSFETs). The current limitation (e.g., the amount of current each transistor is capable of handling) of each of the first transistor 502 and the second transistor 504 determines the holding power of the respective transistor. For example, at any given moment, only one of the first transistor 502 and the second transistor 504 is ON and the other is OFF. Alternatively, the first transistor 502 and the second transistor 504 may both be OFF, but both cannot be ON at same time as the current passing through both will cause damage (e.g., both the first transistor 502 and the second transistor 504 will be broken or burned). As such, a dead time may need to be seat for each of the first transistor 502 and the second transistor 504.

A pulse width modulation (PWM) power on/off control signal 520 is input into one or more logic and dead time adjust circuits 522, which generate two signals, an upper signal 524 (DTQUP) and a lower signal 526 (DTQLOW) after driver 506.

The one or more logic and dead time adjust circuits 522 may set a dead time for a half bridge 500 by adjusting the delay between the turn-off signal of the first transistor 502 (e.g., the high-side switch) and the turn-on signal of the second transistor 504 (low-side switch) or vice versa using a dedicated “dead time” setting on the gate driver of the one or more logic and dead time adjust circuits 522 to create a time window where both the first transistor 502 and the second transistor 504 are OFF. The dead time setting may be a predetermined value or may be computed by the one or more logic and dead time adjust circuits 522 based on characteristics of the first transistor 502 and the second transistor 504.

A bias voltage (V_{BIAS}) 528 is input to a DC supply DC-DC convertor 530 for the logic and dead time adjust circuits 522 and the driver 506. The DC-DC convertor 530 generates two DC supply voltages, a common collector voltage (VCC) 532 and a transistor drain voltage (VDD) 534 with an isolated ground (GND). The VCC 532 relates the GND and the VDD 534 relates to a PGND (Vo), which is floating GND. The isolated buffer amplifier 510 is a buffer amplifier of the positive PWM signals and negative PWM signals of the control signal 520 with an isolated GND (PGND).

Although FIG. 5 illustrates one example of a half bridge to support multiple level envelope tracking, various changes may be made to FIG. 5. For example, various components in FIG. 5 could be combined, further subdivided, or omitted and additional components could be added according to particular needs.

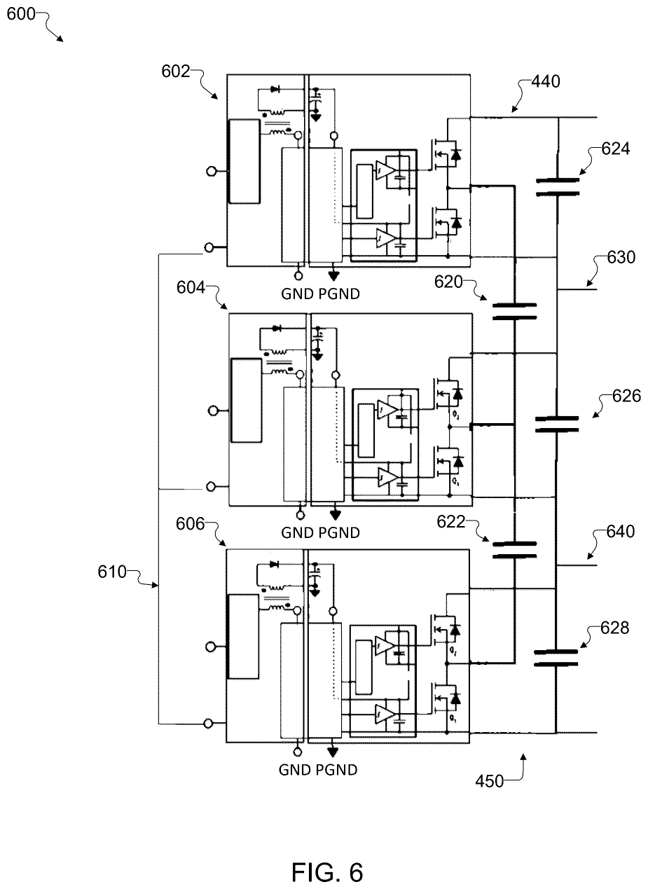

FIG. 6 illustrates an example block diagram of a switch capacitor voltage divider (SCVD) 600 to support multiple level envelope tracking according to embodiments of the present disclosure. The embodiment of the SCVD 600 illustrated in FIG. 6 is for illustration only. Other embodiments of the SCVD 600 could be used without departing from the scope of the present disclosure.

As shown in FIG. 6, the SCVD 600 includes a first half bridge 602, a second half bridge 604, and a fourth half bridge 606. The first half bridge 602, the second half bridge 604, and the fourth half bridge 606 are coupled to each other in series. For example, the first half bridge 602 is coupled to the second half bridge 604 and the second half bridge 604 is coupled to the fourth half bridge 606. The first half bridge 602 and the second half bridge 604 are coupled to a first capacitor 620. Similarly, the second half bridge 604 and the fourth half bridge 606 are coupled to a second capacitor 622. The first capacitor 620 is coupled to a third capacitor 624 and a fourth capacitor 626. The second capacitor 622 is coupled to the fourth capacitor 626 and a fifth capacitor 628.

Each of the first half bridge 602, the second half bridge 604, and the fourth half bridge 606 receive a clock signal 610 that acts as a control signal (e.g., the control signal 520). The first half bridge 602 receives the first voltage 440 as an input voltage, passes the first voltage 440 through its first transistor or second transistor (e.g., the first transistor 502 or the second transistor 504) and outputs a voltage to charge the first capacitor 620. Similarly, the second half bridge 604 charges the first capacitor 620 and the second capacitor 622 while the fourth half bridge 606 only charges the second capacitor 622. The first capacitor 620 discharges its voltage to charge the third capacitor 624 and the fourth capacitor 626 while the second capacitor 622 discharges its voltage to charge the fourth capacitor 626 and the fifth capacitor 628. The first voltage 440 also charges the third capacitor 624 while the second voltage 450 also charges the fifth capacitor 628. The third capacitor 624 and the fourth capacitor 626 discharge and produce a first intermediate voltage 630 having a voltage value of about two-thirds of the voltage difference between the first voltage 440 and the second voltage 450 above the second voltage 450. Similarly, the fourth capacitor 626 and the fifth capacitor 628 discharge and produce a second intermediate voltage 640 having a voltage value of about one-third of the voltage difference between the first voltage 440 and the second voltage 450. The four voltages (e.g., the first voltage 440, the first intermediate voltage 630, the second intermediate voltage 640, and the second voltage 450) are output to a modulator (e.g., the tracker 430).

Although FIG. 6 illustrates one example of a switch capacitor voltage divider to support multiple level envelope tracking, various changes may be made to FIG. 6. One or more half bridges, N, may be used to generate N+1 voltage levels in the SCVD, where Nis an odd integer. For example, one half bridge may generate a two-level SCVD and five half bridges may generate a six-level SCVD.

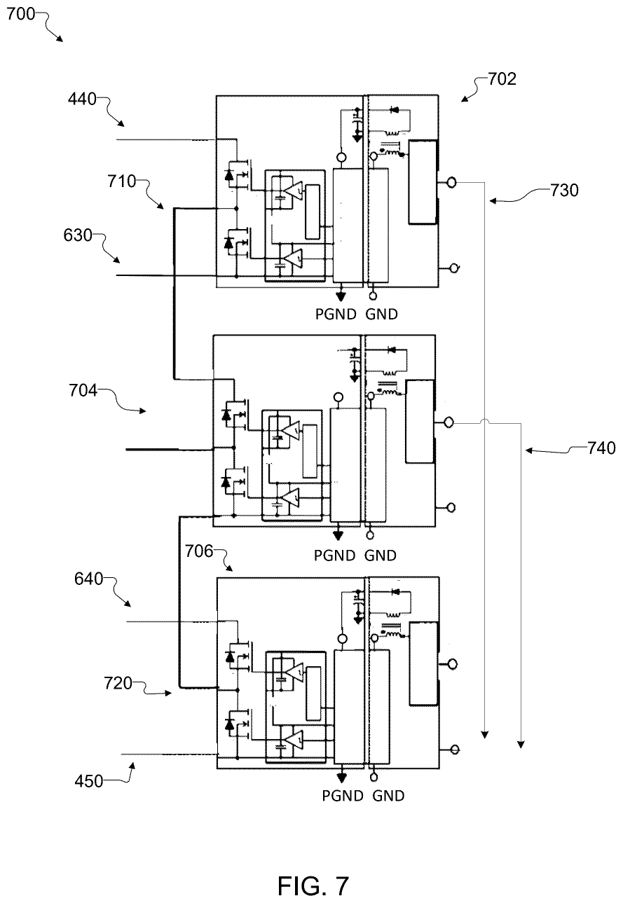

FIG. 7 illustrates an example block diagram of a supply voltage modulator to support multiple level envelope tracking according to embodiments of the present disclosure. The embodiment of the supply voltage tracker 700 illustrated in FIG. 7 is for illustration only. Other embodiments of the supply voltage tracker 700 could be used without departing from the scope of the present disclosure.

As shown in FIG. 7, the supply voltage tracker 700 includes a first half bridge 702, a second half bridge 704, and a third half bridge 706. The first half bridge 702 is configured to receive the first voltage 440 and the first intermediate voltage 630. The first half bridge 702 produces a first modulated PA supply voltage 710 and a first modulated signal 730. The third half bridge 706 is configured to receive the second intermediate voltage 640 and the second voltage 450. The third half bridge 706 produces a second modulated PA supply voltage 720 and a first modulated signal 730. The first modulated PA supply voltage 710 and the second modulated PA supply voltage 720 are input into the second half bridge 704. The second half bridge 704 then produces a second modulated signal 740. Both the first modulated signal 730 and the second modulated signal 740 are provided to a power amplifier to generate a DET voltage level. For example, the amplitudes of the first modulated signal 730 and the second modulated signal 740 may be added to produce a desired voltage level. As the first modulated signal 730 and the second modulated signal 740 fluctuate (e.g., due to different pulse widths) the voltage level may decrease or increase based on the envelope of an input power amplifier (PA) signal.

The supply voltage tracker 700 is a power amplifier DC supply level selector following power level or envelope of the input PA signal. When the input PA signal level is low, for example, the supply voltage tracker 700 reduces the PA drain voltage to reduce energy waste and maintain high signal quality to increase power amplifier efficiency. When the input PA signal is high, the supply voltage tracker 700 increases PA drain voltage to avoid signal saturation.

Although FIG. 7 illustrates one example of a supply voltage modulator to support multiple level envelope tracking, various changes may be made to FIG. 7. One or more half bridges, N, may be used to receive N+1 voltage levels from a generator, where Nis an odd integer. For example, one half bridge may be capable of receiving voltages from a two-level SCVD, five half bridges may be capable of receiving voltages from receive a six-level SCVD, and eight half bridges may be capable of receiving voltages from an eight-level SCVD.

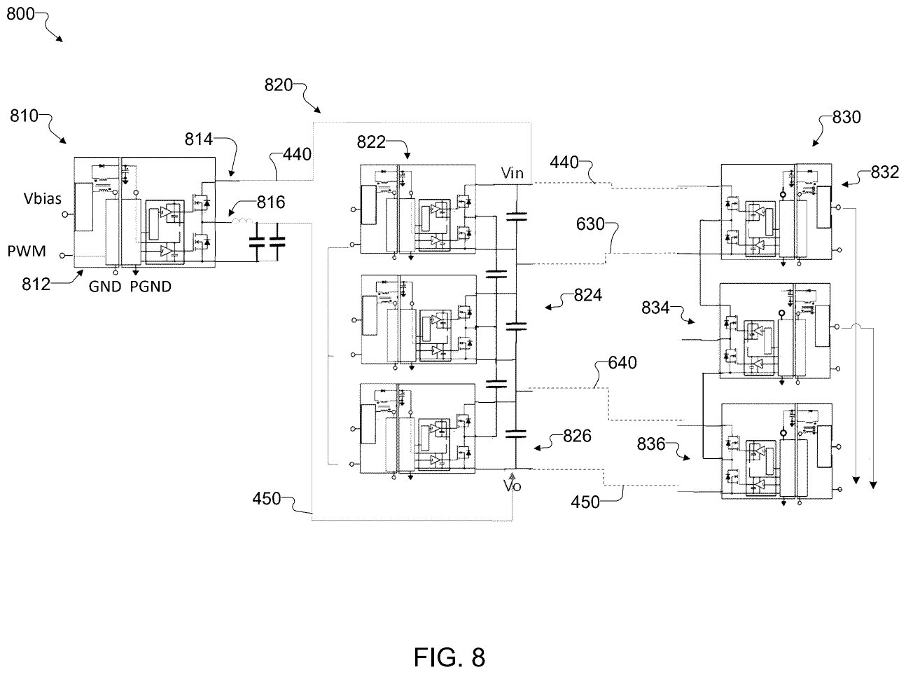

FIG. 8 illustrates an example block diagram of a voltage supply system 800 to support multiple level envelope tracking according to embodiments of the present disclosure. The embodiment of the voltage supply system 800 illustrated in FIG. 8 is for illustration only. Other embodiments of the voltage supply system 800 could be used without departing from the scope of the present disclosure.

As shown in FIG. 8, the voltage supply system 800 includes a DC-DC converter 810 coupled to a generator 820 and a supply voltage tracker 830. The DC-DC converter 810 includes a converter half bridge 812 and configured to receive the first voltage 440 using a converter input 814 and provide the second voltage 450 using a converter output 816 to the generator 820. The converter half bridge 812 of the DC-DC converter 810 may be the half bridge 500 of FIG. 5. The generator 820 includes a first generator half bridge 822, a second generator half bridge 824, and a third generator half bridge 826. The generator 820 is configured similarly to the SCVD 600 of FIG. 6. The generator 820 provides the first voltage 440, the 422 (two shown), and the second voltage 450 to the supply voltage tracker 830. The supply voltage tracker 830 includes a first tracker half bridge 832, a second tracker half bridge 834, and a third tracker half bridge 836. The supply voltage tracker 830 is configured similarly to the supply voltage tracker 700 of FIG. 7.

The voltage supply system 800 is configured as a four-level DC power modulator for use in digital envelope tracking (DET) or power tracking (PT). Although shown using a four-level SCVD and a four-level modulator, the voltage supply system 800 may include any level SCVD and any level modulator. For example, the SCVD may be a two-level SCVD using one half bridge, a three-level SCVD using two half bridges, or a five-level SCVD using four half bridges. Similarly, the modulator may be a two-level modulator using one half bridge, a three-level modulator using two half bridges, or a five-level modulator using four half bridges. In this embodiment, all specifications, such rising time and falling time, max load current hold, and adjusting dead time are completed using half bridges.

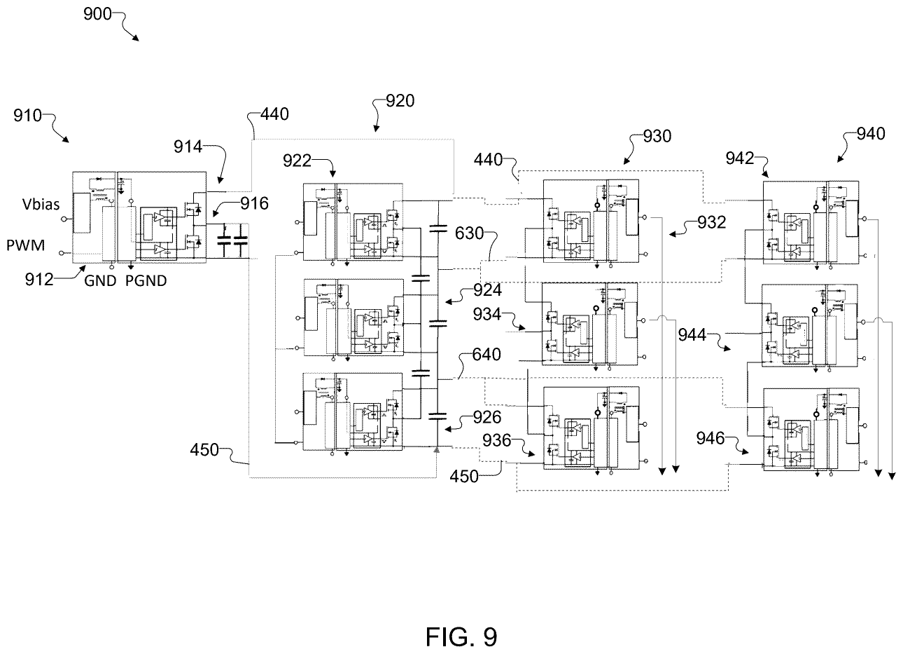

Although FIG. 8 illustrates one example of a voltage supply system to support multiple level envelope tracking, various changes may be made to FIG. 8. For example, multiple modulators may be used in series for a single generator as shown in FIG. 9.

FIG. 9 illustrates an example block diagram of a voltage supply system 900 using multi-level supply voltage modulators to support multiple level envelope tracking according to embodiments of the present disclosure. The embodiment of the voltage supply system 900 illustrated in FIG. 9 is for illustration only. Other embodiments of the voltage supply system 900 could be used without departing from the scope of the present disclosure.

As shown in FIG. 9, the voltage supply system 900 includes a DC-DC converter 910 coupled to a generator 920, a first tracker 930, and a second tracker 940. The DC-DC converter 910 includes a converter half bridge 912 and configured to receive the first voltage 440 using a converter input 914 and provide the second voltage 450 using a converter output 916. The converter half bridge 912 of the DC-DC converter 910 may be the half bridge 500 of FIG. 5. The generator 920 includes a first generator half bridge 922, a second generator half bridge 924, and a third generator half bridge 926. The generator 920 is configured similarly to the SCVD 600 of FIG. 6. The generator 920 provides the first voltage 440, the one or more intermediate voltages 422 (two shown), and the second voltage 450 to the first tracker 930 and the second tracker 940. The first tracker 930 includes a first tracker half bridge 932, a second tracker half bridge 934, and a third tracker half bridge 936. The second tracker 940 includes a fourth tracker half bridge 942, a fifth tracker half bridge 944, and a sixth tracker half bridge 946. The first tracker 930 and the second tracker 940 are configured similarly to the supply voltage tracker 700 of FIG. 7. The first tracker 930 and the second tracker 940 each receive the first voltage 440, the one or more intermediate voltages 422, and the second voltage 450 in parallel and each produce two PWM output signals and provide their respective signals to a power amplifier of a DET system (e.g., the power amplifier 460 of the DET system 400) where the two PWM output signals then combine to produce a power amplifier drain voltage.

The multi-layered modulator (e.g., the first tracker 930 and the second tracker 940) allow for additional PWM output signals to be provided to the power amplifier, resulting in more available voltage levels for envelope tracking without requiring additional generators (e.g., two or more SCVDs) or a higher level generator (e.g., an eight-level SCVD). Alternatively, the multi-layer modulator configuration may support one or more power amplifiers using one of the at least one SCVD. For example, the first tracker 930 may be coupled to a first power amplifier and the second tracker 940 may be coupled to a second power amplifier. This allows the generator 920 to provide the first voltage 440, the one or more intermediate voltages 422, and the second voltage 450 to both the first and second power amplifiers. This configuration may be beneficial to reduce space used by a DET system in MIMO configurations with multiple power amplifiers.

Although FIG. 9 illustrates one example of a voltage supply system using multi-level supply voltage modulators, various changes may be made to FIG. 9. For example, the voltage supply system may include three or more modulators connected in parallel.

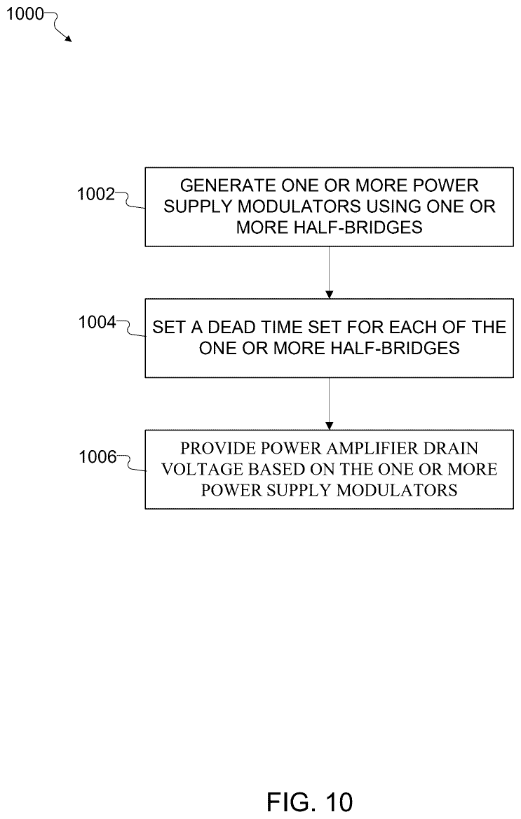

FIG. 10 illustrates an example method 1000 for applying multiple level envelope tracking using multi half bridges according to embodiments of the present disclosure. An embodiment of the method illustrated in FIG. 10 is for illustration only. One or more of the components illustrated in FIG. 10 may be implemented in specialized circuitry configured to perform the noted functions or one or more of the components may be implemented by one or more processors executing instructions to perform the noted functions. Other embodiments of multiple level envelope tracking using multi half bridges could be used without departing from the scope of this disclosure.

As illustrated in FIG. 10, one or more power supply modulators of a digital envelope tracking system are generated using one or more half bridges at step 1002. For example, one or more half bridges 500 may be used to generate at least one SCVD (e.g., the generator 820) and at least one tracker 830 as a DC supply modulator configured to provide the power amplifier drain voltage. This may also include generating at least two trackers (e.g., the first tracker 930 and the second tracker 940) operably coupled to the at least one SCVD (e.g., the SCVD 920).

A dead time is set for each of the one or more half bridges one or more logic and dead time adjust circuits at step 1004. For example, the one or more logic and dead time adjust circuits 522 may set a dead time for a half bridge 500 by adjusting the delay between the turn-off signal of the first transistor 502 (e.g., the high-side switch) and the turn-on signal of the second transistor 504 (low-side switch) or vice versa using a dedicated “dead time” setting on the gate driver of the one or more logic and dead time adjust circuits 522 to create a time window where both the first transistor 502 and the second transistor 504 are OFF. The dead time setting may be a predetermined value or may be computed by the one or more logic and dead time adjust circuits 522 based on characteristics of the first transistor 502 and the second transistor 504.

A power amplifier drain voltage is provided based on the one or more power supply modulators at step 1006. For example, a first voltage 440 and a second voltage 450 may be provided to the generator 920 (e.g., by the DC-DC converter 910). The SCVD 920 may then generate one or more intermediate voltages 422 and subsequently provide the first voltage 440, the one or more intermediate voltages 422, and the second voltage 450 to the first tracker 930. The first tracker 930 receives the first voltage 440, the one or more intermediate voltages 422, and the second voltage 450 and uses them to generate two PWM output signals. The two PWM output signals then combine (e.g., at the power amplifier 460) to produce a power amplifier drain voltage. Additionally, providing a power amplifier drain voltage may include supporting one or more trackers (e.g., the first tracker 930 and the second tracker 940) and one or more power amplifiers using one of the at least one SCVD (e.g., the generator 920).

Although FIG. 10 illustrates one example method for multiple level envelope tracking using multi half bridges, various changes may be made to FIG. 10. For example, while shown as a series of steps, various steps in FIG. 10 could overlap, occur in parallel, occur in a different order, or occur any number of times.

The above flowchart illustrates example methods that can be implemented in accordance with the principles of the present disclosure and various changes could be made to the methods illustrated in the flowcharts herein. For example, while shown as a series of steps, various steps could overlap, occur in parallel, occur in a different order, or occur multiple times. In another example, steps may be omitted or replaced by other steps.

Although the present disclosure has been described with exemplary embodiments, various changes and modifications may be suggested to one skilled in the art. It is intended that the present disclosure encompass such changes and modifications as fall within the scope of the appended claims. None of the description in this application should be read as implying that any particular element, step, or function is an essential element that must be included in the claims scope. The scope of patented subject matter is defined by the claims.

What is claimed is:

1. A power modulator system comprising:
one or more power supply modulators configured to provide a power amplifier drain voltage, each of the one or more power supply modulators comprising:
one or more half bridges including one or more drivers; and
one or more logic and dead time adjust circuits.

2. The power modulator system of claim 1, wherein the one or more power supply modulators comprise at least one switch capacitor voltage divider (SCVD).

3. The power modulator system of claim 2, wherein the at least one SCVD is coupled to at least one tracker and one or more power amplifiers.

4. The power modulator system of claim 1, wherein the one or more power supply modulators comprise at least one SCVD and at least one tracker configured to provide the power amplifier drain voltage.

5. The power modulator system of claim 4, wherein the at least one tracker comprises at least two trackers operably coupled to the at least one SCVD.

6. The power modulator system of claim 1, wherein each of the one or more half bridges comprises a metal-oxide-semiconductor field-effect transistor (MOSFET) or a gallium nitride field-effect transistor (GaNFET).

7. The power modulator system of claim 6, wherein each of the one or more half bridges includes at least one of a driver, a level shifter, an isolated buffer amplifier, a bootstrap, and a low dropout regulator.

8. A method, comprising:
generating one or more power supply modulators using one or more half bridges;
setting a dead time set for each of the one or more half bridges using one or more logic and dead time adjust circuits; and
providing power amplifier drain voltage based on the one or more power supply modulators.

9. The method of claim 8, wherein the one or more power supply modulators comprise at least one switch capacitor voltage divider (SCVD).

10. The method of claim 9, further comprising:
supporting one or more trackers and one or more power amplifiers using one of the at least one SCVD.

11. The method of claim 8, wherein generating the one or more power supply modulators using the one or more half bridges includes generating at least one SCVD and at least one tracker as a DC supply modulator configured to provide the power amplifier drain voltage.

12. The method of claim 11, wherein generating at least one SCVD and at least one tracker comprises generating at least two trackers operably coupled to the at least one SCVD.

13. The method of claim 8, wherein each of the one or more half bridges include at least one of a metal-oxide-semiconductor field-effect transistor (MOSFET) or a gallium nitride field-effect transistor (GaN FET).

14. The method of claim 13, wherein each of the one or more half bridges includes a driver, a level shifter, an isolated buffer amplifier, a bootstrap, and a low dropout regulator.

15. An electronic device, comprising:
one or more trackers;
one or more power amplifiers; and
a processor operably coupled to the one or more trackers and the one or more power amplifiers, configured to cause the electronic device to:
generate one or more power supply modulators using one or more half bridges;
set a dead time set for each of the one or more half bridges using one or more logic and dead time adjust circuits; and
provide power amplifier drain voltage based on the one or more power supply modulators.

16. The electronic device of claim 15, wherein the one or more power supply modulators comprise at least one switch capacitor voltage divider (SCVD).

17. The electronic device of claim 16, wherein the processor is further configured to cause the electronic device to support the one or more trackers and the one or more power amplifiers using one of the at least one SCVD.

18. The electronic device of claim 15, wherein, while generating the one or more power supply modulators using the one or more half bridges, the processor is further configured to cause the electronic device to generate at least one SCVD and at least one tracker as a DC supply modulator configured to provide the power amplifier drain voltage.

19. The electronic device of claim 15, wherein, while generating at least one SCVD and at least one tracker, the processor is further configured to cause the electronic device to generate at least two trackers operably coupled to the at least one SCVD.

20. The electronic device of claim 15, wherein each of the one or more half bridges includes a driver, a level shifter, an isolated buffer amplifier, a bootstrap, and a low dropout regulator.
